(19) United States
(12) Patent Application Publication
(10) Pub. No.: US 2005/0288878 A1
(43) Pub. Date: Dec. 29, 2005

(54) Reserve time calculator, method of calculating a reserve time and battery plant employing the same

(75) Inventor: Patrick K. Ng, Plano, TX (US)

Correspondence Address: HITT GAINES P.C., P.O. BOX 832570, RICHARDSON, TX, 75083, US

(73) Assignee: Tyco Electronics Power Systems, Inc., Mesquite, TX (US)

(21) Appl. No.: 10/868,321

(22) Filed: Jun. 15, 2004

(51) Int. Cl. G01R 31/36; G06F 19/00

(52) U.S. Cl. 702/63

(57) ABSTRACT

The present invention provides a reserve time calculator for use with multiple parallel-connected battery string types. In one embodiment, the reserve time calculator includes a load current estimator configured to employ coefficients corresponding to discharge characteristics of at least two of the multiple parallel-connected battery string types and a reserve time estimate to provide a load current estimate. Additionally, the reserve time calculator also includes a load current adjustor coupled to the load current estimator and configured to adjust the load current estimate to within an acceptable error of an actual load current and provide an adjusted reserve time based thereon.

### TECHNICAL FIELD OF THE INVENTION

The present invention is directed, in general, to power systems and, more specifically, to a reserve time calculator, a method of calculating a reserve time and a battery plant employing the calculator or the method.

### BACKGROUND OF THE INVENTION

Telecommunication switching systems are used to route tens of thousands of calls per second. The failure of such a system, due to either an equipment breakdown or a loss of power, is generally unacceptable since it would result in a loss of millions of voice and data communications along with its corresponding revenue. The traditionally high reliability of telecommunication systems, that users have come to expect, is partially based on the use of redundant equipment including power supplies.

Primary power is normally supplied through commercially available AC voltage. Should the AC voltage become unavailable due to an AC power outage or the failure of one or more of its associated components, a backup power capability supplies the needed voltages and currents to maintain operation of the system. This backup power capability can be provided by a battery plant, which generally includes a number of backup batteries as well as corresponding rectifying, inverting and associated power distribution equipment. The backup batteries provide power to the load in the event an AC power outage occurs. During normal operation, the backup batteries are usually maintained in a substantially fully-charged state to provide as long a duration for backup power as possible.

A battery plant may commonly employ flooded (wet cells) or valve regulated lead acid (sealed) batteries as an energy reserve. Additionally, the battery plant may also use a collection of battery strings that have differing energy delivery capabilities. For example, a site may use batteries having a 1680 ampere-hour capacity and batteries having a 4000 ampere-hour capacity. All of the battery strings employed are connected in parallel to a common output bus thereby providing a common output voltage. However, the load current supplied by each battery string will differ depending on its ampere-hour capability.

In general, a reserve time for the battery plant may be defined as an elapsed time that a battery plant can provide a required load current or power within an acceptable output voltage range. One way of estimating the reserve time is to approximate the current or power associated with each type of battery by comparing the internal resistance of each battery type. For many batteries, however, this approach is not accurate enough since the value of the internal resistance is not precisely known. Additionally, even known values of internal resistance may change in an inconsistent manner as a function of operating time or temperature. Another approach estimates the current or power provided by each battery type using the ratio of their nominal capacities. Both approaches lack the self-consistent checking process of ensuring the same end voltage at the output bus and the same reserve time at the end of discharge for each battery type.

Accordingly, what is needed in the art is a practical way to estimate the reserve time associated with a set of battery strings having differing ampere-hour capabilities.

### SUMMARY OF THE INVENTION

To address the above-discussed deficiencies of the prior art, the present invention provides a reserve time calculator for use with multiple parallel-connected battery string types. In one embodiment, the reserve time calculator includes a load current estimator configured to employ coefficients corresponding to discharge characteristics of at least two of the multiple parallel-connected battery string types and a reserve time estimate to provide a load current estimate. Additionally, the reserve time calculator also includes a load current adjustor coupled to the load current estimator and configured to adjust the load current estimate to within an acceptable error of an actual load current and provide an adjusted reserve time based thereon.

In another aspect, the present invention provides a method of calculating a reserve time for use with multiple parallel-connected battery string types. The method includes employing coefficients corresponding to discharge characteristics of at least two of the multiple parallel-connected battery string types and a reserve time estimate to provide a load current estimate. The method also includes adjusting the load current estimate to within an acceptable error of an actual load current and providing an adjusted reserve time based thereon.

The present invention also provides, in yet another aspect, a battery plant that employs a load having an actual load current. The battery plant includes a first parallel-connected battery string type coupled to the load that has a first ampere-hour capability, and a second parallel-connected battery string type coupled to the load that has a second ampere-hour capability. The battery plant also includes a reserve time calculator, coupled to the first and second parallel-connected battery string types, having a load current estimator that employs coefficients corresponding to discharge characteristics of the first and second parallel-connected battery string types and a reserve time estimate to provide a load current estimate. The reserve time calculator also has a load current adjustor, coupled to the load current estimator, that adjusts the load current estimate to within an acceptable error of the actual load current and provides an adjusted reserve time based thereon.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following descriptions taken in conjunction with the accompanying drawings, in which:

FIG. 1 illustrates an embodiment of a battery plant constructed in accordance with the principles of the present invention;

FIG. 2 illustrates a chart showing discharge characteristics of an embodiment of a battery string employing commercially available battery cells;

FIG. 3 illustrates an intercept chart showing variations of an intercept for the discharge curves of FIG. 2;

FIG. 4 illustrates a slope chart showing variations of a slope for the discharge characteristics of FIG. 2; and

FIG. 5 illustrates a flow chart of an embodiment of a method of calculating a reserve time carried out in accordance with the principles of the present invention.

### DETAILED DESCRIPTION

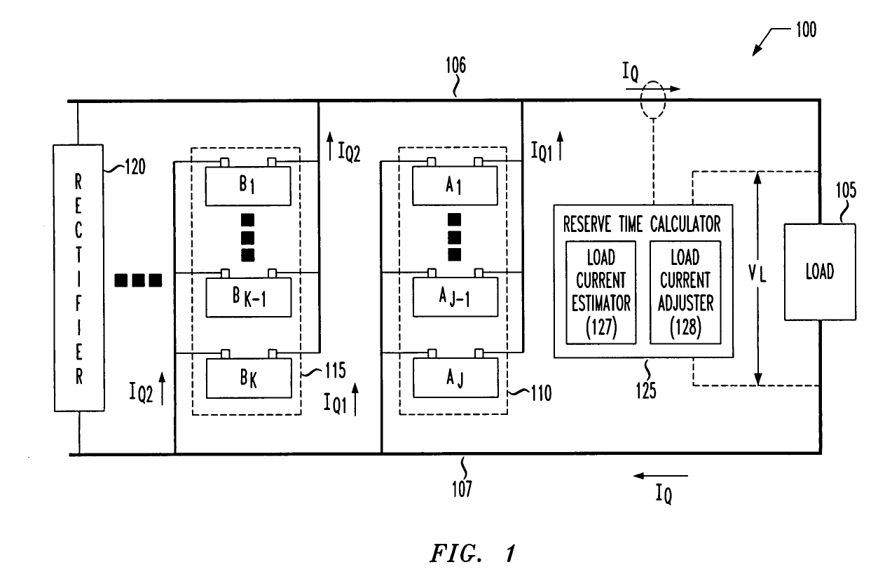

Referring initially to FIG. 1, illustrated is an embodiment of a battery plant, generally designated 100, constructed in accordance with the principles of the present invention. The battery plant 100 includes a load 105 that has an actual load current I_{Q} and is connected between a supply bus 106 and a return bus 107. The battery plant 100 also includes a first parallel-connected battery string 110, a second parallel-connected battery string 115, a rectifier 120 and a reserve time calculator 125 having a load current estimator 127 and a load current adjuster 128. The first and second parallel-connected battery strings 110, 115 are also connected between the supply bus 106 and the return bus 107 and provide the actual load current I_{Q} to the load 105. The rectifier 120 charges the first and second parallel-connected battery strings 110, 115 during normal operations when commercially available AC power is present.

The first parallel-connected battery string 110 includes a plurality of J batteries A₁-A_{J} that are connected in parallel and of a first type having a first ampere-hour capability. Similarly, the second parallel-connected battery string 115 includes a plurality of K batteries B₁-B_{K} that are also connected in parallel and of a second type having a second ampere-hour capability. The first parallel-connected battery string 110 provides a first partial load current I_{Q1}, and the second parallel-connected battery string 115 provides a second partial load current I_{Q2}, wherein the actual load current I_{Q} equals I_{Q1}+I_{Q2}.

Discharge characteristics may be associated with each of the first and second parallel-connected battery strings 110, 115. The discharge characteristics relate discharge current to discharge time for specific values of end-of-discharge (EOD) voltage and are commonly provided for a battery type in tabular form. The discharge characteristics may also be represented by a suite of discharge curves, which may commonly be referred to as Peukert curves. In the illustrated embodiment of the present invention, the reserve time calculator 125 associates an intercept and a slope with each of these discharge curves.

The reserve time calculator 125 may monitor the actual load current I_{Q} or be provided with its value along with a load voltage V_{L}. The actual load current I_{Q} is employed by the reserve time calculator 125, and the load voltage V_{L} may be employed to monitor a proximity to a selected EOD voltage, as appropriate to a specific application. The reserve time calculator 125 also employs coefficients that are associated with the discharge characteristics discussed above. Some of the coefficients correspond to intercepts of the discharge characteristics and are employed in a polynomial, which is a function of a selected EOD voltage, to determine associated intercepts. Others of the coefficients correspond to slopes of the discharge characteristics and are employed in another polynomial, which is also a function of the selected EOD voltage, to determine associated slopes. The reserve time calculator 125 may calculate the coefficients as needed or access a coefficient database as a particular application dictates.

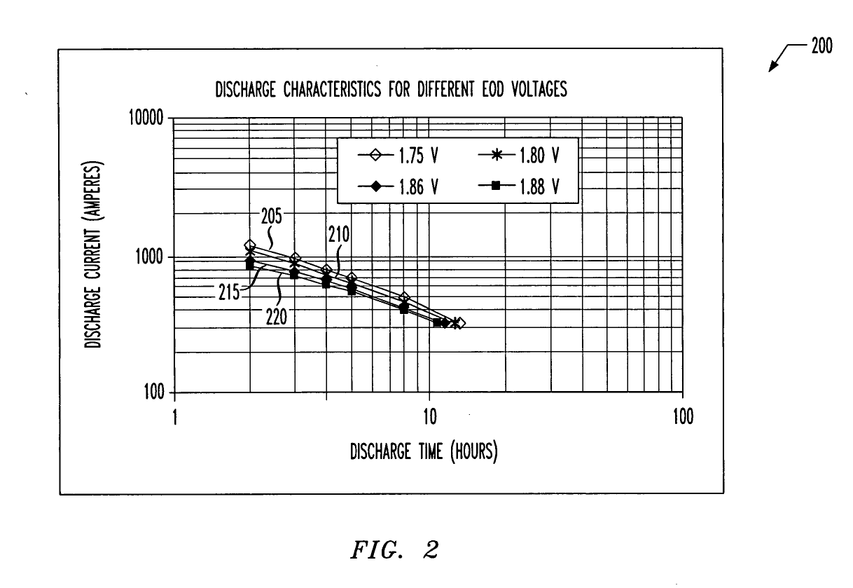

The coefficients and a reserve time estimate are employed to provide a load current estimate that is adjusted iteratively to within an acceptable error of the actual load current I_{Q}. An adjusted reserve time is then based on the adjusted load current estimate. The acceptable error may be based on the value of adjusted reserve time. For example, if the adjusted reserve time is large, an acceptable error of one to ten percent may be quite adequate. As the adjusted reserve time diminishes to a few hours or even minutes, the acceptable error may typically diminish to less than one percent and perhaps to even less than a tenth of one percent. Further discussion of these coefficients is presented below with respect to FIGS. 2, 3 and 4.

With continued reference to FIG. 1 and turning momentarily to FIG. 2, illustrated is a chart showing discharge characteristics, generally designated 200, of an embodiment of a battery string employing a type of commercially available battery cells (MCT-4000 battery cells manufactured by C&D Technologies Inc.). The discharge characteristics 200 include first, second, third and fourth discharge curves 205, 210, 215, 220. As shown, each of the discharge curves 205-220 correspond to an EOD voltage and may be represented by appropriate intercepts and slopes.

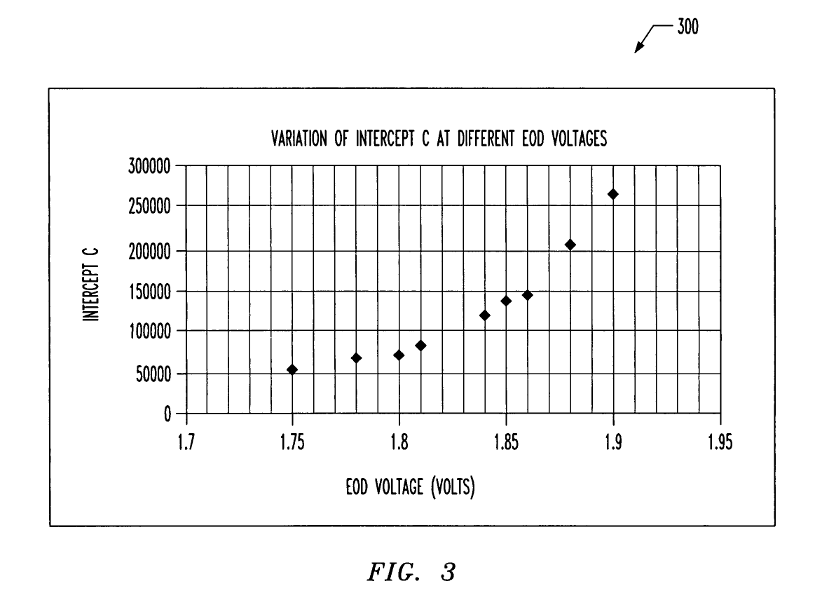

Turning momentarily now to FIG. 3, illustrated is an intercept chart, generally designated 300, showing variations of an intercept C for the discharge curves of FIG. 2. The intercept chart 300 includes a suite of intercept values as a function of EOD voltage. In the illustrated embodiment, a third order polynomial may be fitted to the intercept values shown having the form expressed in equation (1) below:
C=A+B*(EOD)+D*(EOD)²+E(EOD)³, (1)

where A, B, D and E are coefficients associated with the intercept C and EOD is the selected EOD voltage for the battery. Table 1 indicates specific intercept coefficients that may be employed in equation (1) for five commonly used battery types.

TABLE 1
Intercept coefficients

| BATTERY | | | | |
|---|---|---|---|---|
| TYPE | A | B | D | E |
| MCT-4000 | −265,523,770 | 4.54E+08 | −2.59E+08 | 49,350,168 |
| L508 | 6,241,225 | −1E+07 | 5,829,096 | −1,082,240 |
| RC-L1S | 0.39261839 | 5,000,868 | −5,757,519 | 1.66E+06 |
| GU-41 | 3,596,721 | −4,171,763 | 1,221,394 | 0 |
| GU-45 | 2.06E+06 | −2.43E+06 | 7.30E+05 | 0 |

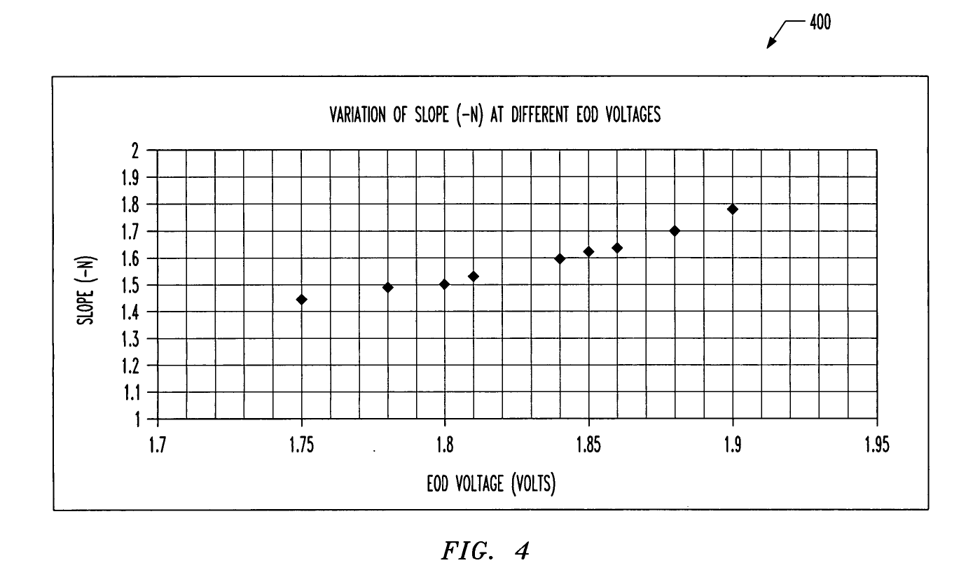

Turning momentarily now to FIG. 4, illustrated is a slope chart, generally designated 400, showing variations of a slope N for the discharge characteristics of FIG. 2. The slope chart 400 includes a suite of slope values as a function of EOD voltage. In the illustrated embodiment, a second order polynomial may be fitted to the slope values shown having the form expressed in equation (2) below:
N=X+Y(EOD)+Z(EOD)², (2)

where X, Y and Z are coefficients associated with the slope N and EOD is again the selected EOD voltage for the battery. Table 2 indicates specific slope coefficients that may be employed in equation (2) for the same five commonly used battery types.

TABLE 2
Slope Coefficients

| BATTERY | | | |
|---|---|---|---|
| TYPE | X | Y | Z |
| MCT-4000 | 25.38063 | −28.332439 | 8.368964 |
| L508 | 3.35531 | −2.8973198 | 0.987356 |
| RC-L1S | 9.95E−05 | −1.3352619 | 1.223838 |
| GU-41 | 13.04151 | −14.002806 | 4.193185 |
| GU-45 | 9.906253 | −10.476122 | 3.196236 |

Returning again to FIG. 1, the load current estimator 127 employs the coefficients corresponding to the discharge characteristics that are associated with the intercept and slope along with a reserve time estimate to provide an initial load current estimate. The load current adjuster 128 is coupled to the load current estimator 127 and iteratively adjusts the initial load current estimate to within an acceptable error of the actual load current I_{Q}. The load current adjuster 127 provides a reserve time for the battery plant 100 when this acceptable error has been achieved. Several examples of battery string combinations are discussed below.

A first example employs first and second parallel-connected battery strings 110, 115 having MCT-4000 and L508 battery cells, respectively. The first example assumes an actual load current I_{Q} equal to 1000 amperes and an EOD voltage equal to 1.75 volts. A reserve time estimate of eight hours is initially assumed. Values for the intercept C and the slope N are calculated from equations (1) and (2) for coefficients selected from TABLE 1 and TABLE 2, respectively. Then, first and second partial load current estimates I_{E1}, I_{E2} may be calculated for each of the first and second battery strings 110, 115 employing an equation (3):
t=C*I^{-N} (3)

where t is the reserve time, C is the intercept, I is the battery-string current and N is the slope. Table 3A shows pertinent data and results associated with this initial iteration.

TABLE 3A

| BATTERY | | | PARTIAL LOAD |
|---|---|---|---|
| TYPE | INTERCEPT C | SLOPE N | CURRENT ESTIMATES |
| MCT-4000 | 53949.75 | 1.428814 | 478.3825 Amps |
| L508 | 8440.04 | 1.308778 | 204.1653 Amps |

A load current estimate I_{E} is equal to the sum of first and second partial load current estimates I_{E1}, I_{E2}, which yields a value of 682.5478 amperes. Then, a ratio of the actual to estimated load currents I_{Q}/I_{E} provides a scale factor of 1.465099, which is employed in the next iteration to scale the first and second partial load current estimates I_{E1}/I_{E2}. Equation (3) is again employed, but in this iteration it provides revised first and second reserve times using the scaled first and second load current estimates I_{E1}, I_{E2}. TABLE 3B summarizes these results.

TABLE 3B

| | SCALED PARTIAL LOAD | | | REVISED |
|---|---|---|---|---|
| BATTERY TYPE | CURRENT ESTIMATES | INTERCEPT C | SLOPE N | RESERVE TIMES |
| MCT-4000 | 700.8777 Amps | 53949.75 | 1.428814 | 4.6355 hrs. |
| L508 | 299.1223 Amps | 8440.04 | 1.308778 | 4.8529 hrs. |

The revised first and second reserve times are averaged using simple averaging to provide an average revised reserve time of 4.7442 hours.

This average revised reserve time is employed to calculate first and second revised partial load current estimates I_{E1}, I_{E2} using equation (3), and TABLE 3C summarizes the results.

TABLE 3C

| BATTERY | | | REVISED PARTIAL LOAD |
|---|---|---|---|
| TYPE | INTERCEPT C | SLOPE N | CURRENT ESTIMATES |
| MCT-4000 | 53949.75 | 1.428814 | 689.5966 Amps |
| L508 | 8440.04 | 1.308778 | 304.3462 Amps |

This load current estimate I_{E} is equal to a value of 993.9428 amperes. Then, a ratio of the actual to estimated load currents I_{Q}/I_{E} provides a scale factor of 1.006094, which is employed in the next iteration to scale the first and second partial load current estimates I_{E1}, I_{E2} and use them to calculate revised first and second reserve times. TABLE 3D summarizes these results.

TABLE 3D

| BATTERY | SCALED PARTIAL LOAD | | | REVISED |
|---|---|---|---|---|
| TYPE | CURRENT ESTIMATES | INTERCEPT C | SLOPE N | RESERVE TIMES |
| MCT-4000 | 693.9790 Amps | 53949.75 | 1.428814 | 4.7032 hrs. |
| L508 | 306.2010 Amps | 8440.04 | 1.308778 | 4.7066 hrs. |

The revised first and second reserve times are again averaged using simple averaging to provide an average revised reserve time of 4.7049 hours that is again employed to calculate first and second revised partial load current estimates I_{E1}, I_{E2} using equation (3). TABLE 3E shows the results.

TABLE 3E

| BATTERY | | | REVISED PARTIAL LOAD |
|---|---|---|---|
| TYPE | INTERCEPT C | SLOPE N | CURRENT ESTIMATES |
| MCT-4000 | 53949.75 | 1.428814 | 693.6220 Amps |
| L508 | 8440.04 | 1.308778 | 306.2863 Amps |

This load current estimate I_{E} is equal to a value of 999.9082 amperes, which provides an error of 0.00918 percent that is deemed acceptable for the present example. The adjusted reserve time for the battery plant 100 is then 4.7049 hours.

A second example employs one parallel-connected battery string 110 having MCT-4000 battery cells, two parallel-connected battery strings 115 having L508 battery cells and one parallel-connected battery string 120 having RC-L1S battery cells (not specifically shown in FIG. 1). This example also assumes an actual load current I_{Q} equal to 1000 amperes and an EOD voltage equal to 1.75 volts. The actual load current I_{Q} equals I_{Q1}+I_{Q2}+I_{Q3}, for this example, where a third partial load current I_{Q3} is provided by the parallel-connected battery string 120. A reserve time estimate of four hours is initially assumed. As before, values for the intercept C and the slope N are calculated from equations (1) and (2) for coefficients selected from TABLE 1 and TABLE 2, respectively. Then, first, second and third partial load current estimates I_{E1}, I_{E2}, I_{E3} may be calculated for each of the battery strings 110, 115, 120 employing equation (3) wherein TABLE 4A summarizes the results.

TABLE 4A

| BATTERY | | | PARTIAL LOAD |
|---|---|---|---|
| TYPE | INTERCEPT C | SLOPE N | CURRENT ESTIMATES |
| MCT-4000 | 53949.75 | 1.428814 | 777.0708 Amps |
| L508 | 8440.04 | 1.308778 | 346.7291 Amps |
| RC-L1S | 1.365E+04 | 1.411395 | 318.6728 Amps |

The load current estimate I_{E} is equal to the sum of the partial load current estimates I_{E1}, I_{E2}, I_{E3}, which yields a value of 2107.875 amperes. Then, a ratio of actual to estimated load currents I_{Q}/I_{E} provides a scale factor of 0.474411, which is employed in the next iteration to scale the partial load current estimates I_{E1}, I_{E2}, I_{E3}. Equation (3) is again employed and again this iteration provides revised first, second and third reserve times using these scaled partial load current estimates I_{E1}, I_{E2}, I_{E3}. TABLE 4B summarizes these results.

TABLE 4B

| BATTERY | SCALED PARTAL LOAD | | | REVISED |
|---|---|---|---|---|
| TYPE | CURRENT ESTIMATES | INTERCEPT C | SLOPE N | RESERVE TIMES |
| MCT-4000 | 368.6513 Amps | 53949.75 | 1.428814 | 11.6084 hrs. |
| L508 | 164.4923 Amps | 8440.04 | 1.308778 | 10.6145 hrs. |
| RC-L1S | 151.1821 Amps | 13654.28 | 1.411395 | 11.4586 hrs. |

These revised reserve times are averaged using simple averaging to provide an average revised reserve time of 11.2272 hours.

This average revised reserve time is again employed to calculate revised partial load current estimates I_{E1}, I_{E2}, I_{E3} using equation (3), and TABLE 4C summarizes the results.

TABLE 4C

| BATTERY | | | REVISED PARTIAL LOAD |
|---|---|---|---|
| TYPE | INTERCEPT C | SLOPE N | CURRENT ESTIMATES |
| MCT-4000 | 53949.75 | 1.428814 | 157.5886 Amps |
| L508 | 8440.04 | 1.308778 | 377.3685 Amps |
| RC-L1S | 1.365E+04 | 1.411395 | 153.3835 Amps |

This load current estimate I_{E} is equal to a value of 999.9082 amperes, which provides an error of 0.06874 percent that is acceptable for this example. The adjusted reserve time for the battery plant 100 is then 11.2272 hours. Although simple averaging of the revised reserve times was employed to arrive at the adjusted reserve time in the exemplary embodiments presented above, a weighted averaging or geometric averaging may also be advantageously applied as appropriate to a particular application.

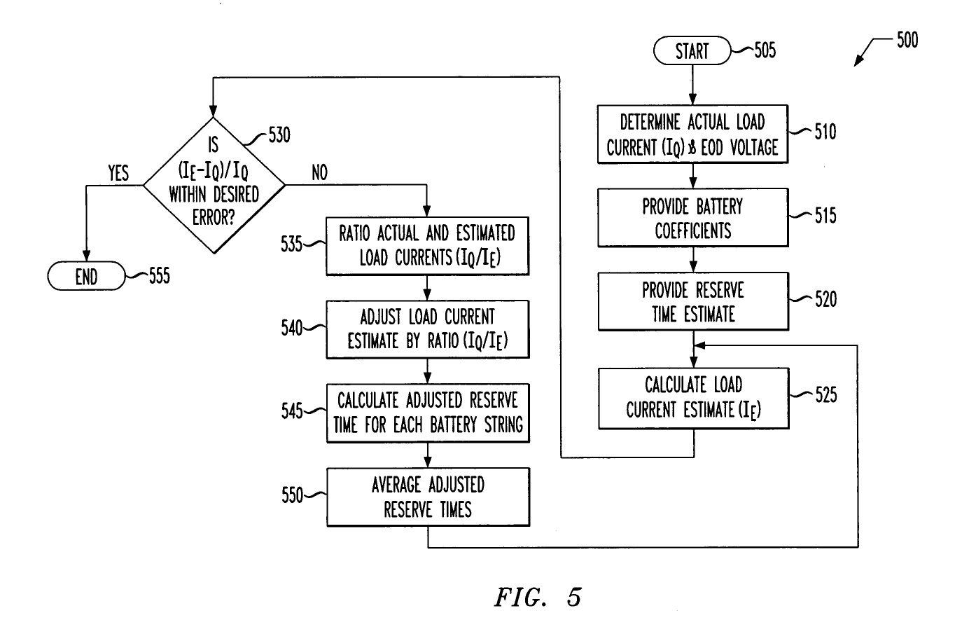

Turning now to FIG. 5, illustrated is a flow chart of an embodiment of a method of calculating a reserve time, generally designated 500, carried out in accordance with the principles of the present invention. The method 500 starts in a step 505 and may be used with multiple parallel-connected battery string types having different ampere-hour capabilities. An actual load current (I_{Q}) and a required end-of-discharge (EOD) voltage are determined in a step 510. Then, battery coefficients are provided in a step 515. These coefficients correspond to discharge characteristics of at least two of the multiple parallel-connected battery string types and may be calculated as needed or precalculated and stored in a database until needed.

In the method 500, some of the coefficients correspond to intercepts of the discharge characteristics and are employed in a polynomial that is a function of the end-of-discharge voltage to determine these intercepts. Additionally, some of the coefficients alternatively correspond to slopes of the discharge characteristics and are employed in another polynomial that is also a function of the end-of-discharge voltage to determine these slopes. A reserve time estimate is provided in a step 520 and along with the coefficients provided in the step 515, a load current estimate (I_{E}) is calculated in a step 525. Calculation of the load current estimate in the step 525 involves calculating a partial load current estimate for each of the multiple parallel-connected battery string types being employed and adding these together to yield the load current estimate.

A decisional step 530 determines if the load current estimate is within an acceptable error of the actual load current. If the load current estimate is not within the acceptable error, a ratio of the actual load current to the load current estimate is provided in a step 535. Then, the load current estimate is adjusted by this ratio in a step 540 by providing an adjusted-value for each of the partial load current estimates. These adjusted-value partial load current estimates are then employed to calculate adjusted reserve times for each of the contributing multiple parallel-connected battery string types. This set of adjusted reserve times is then averaged to provide an average adjusted reserve time in a step 550. The averaging operation may employ at least one operation selected from the group consisting of a simple average, a weighted average and a geometric average.

The method 500 returns to the step 525 wherein the average adjusted reserve time provided in the step 550 is used as a basis to calculate another load current estimate. The decisional step 530 again determines if this load current estimate is within the acceptable error of the actual load current. If this load current estimate is not within the acceptable error, adjustment of the load current estimate is performed iteratively until the acceptable error is achieved. When the acceptable error is achieved, the last iteration of the step 550 provides the appropriately adjusted reserve time until the selected end-of-discharge voltage occurs, and the method 500 ends in a step 555.

While the method disclosed herein has been described and shown with reference to particular steps performed in a particular order, it will be understood that these steps may be combined, subdivided, or reordered to form an equivalent method without departing from the teachings of the present invention. Accordingly, unless specifically indicated herein, the order or the grouping of the steps are not limitations of the present invention.

In summary, embodiments of the present invention employing a reserve time calculator, a method of calculating a reserve time and a battery plant employing the calculator or the method have been presented. Advantages include the ability to calculate the reserve time for a collection of mixed battery string types that are connected in parallel to a common load. Calculation of the reserve time employs two sets of coefficients used in polynomial representations to calculate slope and intercept values associated with battery type discharge characteristics. The reserve time is then calculated in an iterative manner to an acceptable accuracy without having to employ a value of internal resistance for the associated batteries.

Although the present invention has been described in detail, those skilled in the art should understand that they can make various changes, substitutions and alterations herein without departing from the spirit and scope of the invention in its broadest form.

1. A reserve time calculator for use with multiple parallel-connected battery string types, comprising:
a load current estimator configured to employ coefficients corresponding to discharge characteristics of at least two of said multiple parallel-connected battery string types and a reserve time estimate to provide a load current estimate; and
a load current adjustor coupled to said load current estimator and configured to adjust said load current estimate to within an acceptable error of an actual load current and provide an adjusted reserve time based thereon.

2. The calculator as recited in claim 1 wherein some of said coefficients correspond to intercepts of said discharge characteristics.

3. The calculator as recited in claim 2 wherein said some of said coefficients are employed in a polynomial that is a function of an end-of-discharge voltage to determine said intercepts.

4. The calculator as recited in claim 1 wherein some of said coefficients correspond to slopes of said discharge characteristics.

5. The calculator as recited in claim 4 wherein said some of said coefficients are employed in a polynomial that is a function of an end-of-discharge voltage to determine said slopes.

6. The calculator as recited in claim 1 wherein said load current estimate is iteratively adjusted until said acceptable error is achieved.

7. The calculator as recited in claim 1 wherein said adjusted reserve time employs at least one operation selected from the group consisting of:
a simple average,
a weighted average, and
a geometric average.

8. A method of calculating a reserve time for use with multiple parallel-connected battery string types, comprising:
employing coefficients corresponding to discharge characteristics of at least two of said multiple parallel-connected battery string types and a reserve time estimate to provide a load current estimate;
adjusting said load current estimate to within an acceptable error of an actual load current; and
providing an adjusted reserve time based thereon.

9. The method as recited in claim 8 wherein some of said coefficients correspond to intercepts of said discharge characteristics.

10. The method as recited in claim 9 wherein said some of said coefficients are employed in a polynomial that is a function of an end-of-discharge voltage to determine said intercepts.

11. The method as recited in claim 8 wherein some of said coefficients correspond to slopes of said discharge characteristics.

12. The method as recited in claim 11 wherein said some of said coefficients are employed in a polynomial that is a function of an end-of-discharge voltage to determine said slopes.

13. The method as recited in claim 8 wherein said adjusting said load current estimate is performed iteratively until said acceptable error is achieved.

14. The method as recited in claim 8 wherein said providing said adjusted reserve time employs at least one operation selected from the group consisting of:
a simple average,
a weighted average, and
a geometric average.

15. A battery plant, comprising:
a load that has an actual load current;
a first parallel-connected battery string type coupled to said load that has a first ampere-hour capability;
a second parallel-connected battery string type coupled to said load that has a second ampere-hour capability; and
a reserve time calculator coupled to said first and second parallel-connected battery string types, including:
a load current estimator that employs coefficients corresponding to discharge characteristics of said first and second parallel-connected battery string types and a reserve time estimate to provide a load current estimate; and
a load current adjustor, coupled to said load current estimator, that adjusts said load current estimate to within an acceptable error of said actual load current and provides an adjusted reserve time based thereon.

16. The battery plant as recited in claim 15 wherein some of said coefficients correspond to intercepts of said discharge characteristics.

17. The battery plant as recited in claim 16 wherein said some of said coefficients are employed in a polynomial that is a function of an end-of-discharge voltage to determine said intercepts.

18. The battery plant as recited in claim 15 wherein some of said coefficients correspond to slopes of said discharge characteristics.

19. The battery plant as recited in claim 18 wherein said some of said coefficients are employed in a polynomial that is a function of an end-of-discharge voltage to determine said slopes.

20. The battery plant as recited in claim 15 wherein said load current estimate is iteratively adjusted until said acceptabled error is achieved.

21. The battery plant as recited in claim 15 wherein said adjusted reserve time employs at least one operation selected from the group consisting of:
a simple average,
a weighted average, and
a geometric average.
